(19) United States
(12) Patent Application Publication
(10) Pub. No.: US 2019/0353715 A1
(43) Pub. Date: Nov. 21, 2019

(54) FAILURE DETECTION DEVICE FOR ONBOARD POWER SUPPLY DEVICE, AND ONBOARD POWER SUPPLY DEVICE

(71) Applicants: AutoNetworks Technologies, Ltd., Yokkaichi, Mie (JP); Sumitomo Wiring Systems, Ltd., Yokkaichi, Mie (JP); Sumitomo Electric Industries, Ltd., Osaka-Shi (JP)

(72) Inventor: Atsushi MIKI, Yokkaichi, Mie (JP)

(21) Appl. No.: 16/476,336

(22) PCT Filed: Dec. 20, 2017
(86) PCT No.: PCT/JP2017/045688

§ 371 Date: Jul. 8, 2019

(30) Foreign Application Priority Data
Jan. 9, 2017 (JP) 2017-001498

(51) Int. Cl. G01R 31/40; H02M 3/155

(52) U.S. Cl. CPC G01R 31/40; H02M 1/08; H02M 3/155

(57) ABSTRACT

In a failure detection device, a signal output portion outputs an inspection instruction signal for instructing a plurality of abnormality detection circuits to perform an operation that is to be performed in case of abnormality, via a shared signal line. A signal distribution portion transmits the inspection instruction signal output from the signal output portion to the shared signal line to the abnormality detection circuits through a plurality of branch signal lines. A determination portion determines whether or not each of the abnormality detection circuits has failed, based ON signals output from the plurality of abnormality detection circuits when the signal output portion has output the inspection instruction signal via the shared signal line.

### CROSS-REFERENCE TO RELATED APPLICATIONS

This application is the U.S. national stage of PCT/JP2017/045688 filed on Dec. 20, 2017, which claims priority of Japanese Patent Application No. JP 2017-001498 filed on Jan. 9, 2017, the contents of which are incorporated herein.

### TECHNICAL FIELD

The present disclosure relates to a failure detection device for an onboard power supply device, and an onboard power supply device.

### BACKGROUND

JP 2015-100240A discloses an example of an onboard power supply device, and also discloses a protection device for protecting this power supply device. The power supply device disclosed in JP 2015-100240A operates to increase or decrease an input DC voltage, and performs control such that an output voltage is a set target voltage. The protection device includes a determination means for determining whether or not an overcurrent has occurred in the power supply device, and performs control to stop operation of an electronic device if the determination means determines that an overcurrent is flowing.

An abnormality detection circuit for detecting an abnormal state, such as the occurrence of an overcurrent or an overvoltage, is often mounted in an onboard power supply device, and this kind of abnormality detection circuit is characterized in that the frequency with which it operates is very low, since it is basically configured to operate when an abnormal state has occurred within the power supply device. For example, if no abnormality occurs for a long time period in the power supply device, a long time period will elapse while the abnormality detection circuit remains unoperated.

However, the longer the period during which the abnormality detection circuit is stopped (i.e. the period during which the abnormality detection circuit waits until an abnormality occurs), it is more likely that the abnormality detection circuit itself will fail during this period. If the abnormality detection circuit itself fails during the period during which it is stopped, there is a concern that an abnormal state will not be detected and will be left unattended even if this abnormal state, which is to be detected by the abnormality detection circuit, occurs within the power supply device after the abnormality detection circuit has failed.

The present disclosure has been made based on the foregoing circumstance, and aims to realize a failure detection device capable of determining, in a shorter time period, whether or not a failure has occurred in at least one of a plurality of detection circuits capable of detecting a failure that occurs in an onboard power supply device.

### SUMMARY

A failure detection device for detecting a failure in an onboard power supply device includes a voltage conversion portion that is connected to a first conductive path and a second conductive path, and at least performs an operation to increase or reduce a voltage applied to one of the first conductive path and the second conductive path and output the increased or reduced voltage to the other one of the first conductive path and the second conductive path. A control portion controls the voltage conversion portion. An abnormality detection portion includes a plurality of abnormality detection circuits for detecting an abnormality in a current or a voltage occurring at a plurality of detection target positions, and outputs an abnormality detection signal if any of the abnormality detection circuits has detected an abnormality in a current or a voltage, the failure detection device including. A signal output portion outputs, via a shared signal line, an inspection instruction signal for instructing the abnormality detection circuits to perform an operation that is to be performed in case of abnormality. A signal distribution portion includes a plurality of branch signal lines branching from the shared signal line, and transmits the inspection instruction signal output from the signal output portion to the shared signal line to the abnormality detection circuits through the respective branch signal lines. A determination portion determines whether or not each of the abnormality detection circuits has failed, based on a signal output from each of the abnormality detection circuits when the signal output portion has output the inspection instruction signal via the shared signal line.

An onboard power supply device according to a second disclosure includes the voltage conversion portion, the control portion, the abnormality detection portion, and the failure detection device.

### Advantageous Effects of Disclosure

In the failure detection device according to the first disclosure, the signal output portion outputs the inspection instruction signal (a signal for instructing the abnormality detection circuits to perform the operation that is to be performed in case of abnormality) via the shared signal line. The signal distribution portion transmits the inspection instruction signal output from the signal output portion to the shared signal line to the abnormality detection portions through the plurality of branch signal lines. Due to this configuration, the plurality of abnormality detection circuits can be caused to perform the operation that is to be performed in case of abnormality even when no abnormality has actually occurred at the detection target positions of the abnormality detection circuits. Furthermore, since the determination portion is provided, whether or not each of the abnormality detection circuits has failed can be determined based on the signals that are output from the abnormality detection circuits at this time. Moreover, the plurality of abnormality detection circuits can be simultaneously instructed to perform the operation that is to be performed in case of abnormality, and these abnormality detection circuits can be caused to promptly perform an operation for inspection. Thus, whether or not a failure has occurred in at least one of the plurality of abnormality detection circuits can be determined in a shorter time.

The onboard power supply device according to the second disclosure exhibits effects similar to those of the first disclosure.

### BRIEF DESCRIPTION OF DRAWINGS

FIG. 1 is a circuit diagram that schematically shows an onboard power supply system that includes an onboard power supply device according to Embodiment 1.

FIG. 2 is a block diagram that schematically shows a failure detection device in the onboard power supply device according to Embodiment 1.

FIG. 3 is a block diagram that shows a specific example of the failure detection device in FIG. 2 in a simplified manner.

FIG. 4 is a circuit diagram that shows an example of an abnormality detection circuit and a configuration therearound.

FIG. 5 is a flowchart that shows an example of a flow of abnormality detection control performed by a control portion.

FIG. 6 is a flowchart that shows an example of a flow of failure detection control performed by the control portion.

FIG. 7 is a circuit diagram that schematically shows an onboard power supply system that includes an onboard power supply device according to Embodiment 2.

FIG. 8 is a circuit diagram that schematically shows an onboard power supply system that includes an onboard power supply device according to another embodiment.

### DETAILED DESCRIPTION OF PREFERRED EMBODIMENTS

Preferable examples of the disclosure will now be described.

The abnormality detection portion may include, as the plurality of abnormality detection circuits, an output current abnormality detection circuit for detecting an abnormality in a current in a conductive path on an output side of the voltage conversion portion, and an output voltage abnormality detection circuit for detecting an abnormality in a voltage in the conductive path on the output side. The signal distribution portion may distribute the inspection instruction signal output from the signal output portion to the shared signal line at least to the output current abnormality detection circuit and the output voltage abnormality detection circuit.

The failure detection device that is thus configured can simultaneously inspect the abnormality detection circuit (output current abnormality detection circuit) for detecting an abnormality in a current in the conductive path on the output side, and the abnormality detection circuit (output voltage abnormality detection circuit) for detecting an abnormality in a voltage in the conductive path on the output side, and can determine, in a shorter time, whether or not a failure has occurred in either one of the abnormality detection circuits that can detect abnormalities at critical positions.

The voltage conversion portion may include a first element constituted by a switching element that is electrically connected to the first conductive path, a second element constituted by a switching element or a diode that is electrically connected between the first conductive path and a reference conductive path whose potential is kept at a predetermined reference potential that is lower than a potential in the first conductive path, and an inductor that is electrically connected between the first and second elements and the second conductive path. The abnormality detection portion may include, as one of the abnormality detection circuits, an abnormality detection circuit on a reference conductive path side for detecting an abnormality in a current flowing between the second element and the reference conductive path. The signal distribution portion may distribute the inspection instruction signal output from the signal output portion to the shared signal line at least to the abnormality detection circuit on the reference conductive path side.

The failure detection device that is thus configured can simultaneously inspect the abnormality detection circuit on the reference conductive path side together with the other abnormality detection circuits, and can determine, in a shorter time, whether or not a failure has occurred in the abnormality detection circuits that can detect abnormalities at critical positions.

The onboard power supply device may be provided with a plurality of the voltage conversion portions. The abnormality detection portion may be provided with one or more abnormality detection circuits in association with the respective voltage conversion portions. The signal distribution portion may distribute the inspection instruction signal output from the signal output portion to the shared signal line to the abnormality detection circuits associated with the respective voltage conversion portions.

The failure detection device that is thus configured can simultaneously inspect the plurality of abnormality detection circuits that are associated with the respective voltage conversion portions in the onboard power supply device that includes the plurality of voltage conversion portions and is configured as a multi-phase type, and can determine, in a shorter time, whether or not a failure has occurred in the abnormality detection circuits even in the power supply device of the multi-phase type in which the number of abnormality detection circuits tends to increase.

The abnormality detection portion may include: a plurality of signal transmission paths corresponding to the respective detection target positions; a plurality of voltage signal input portions for applying voltage signals each corresponding to a voltage or a current at a corresponding one of the detection target positions to the respective signal transmission paths; and a plurality of comparison portions corresponding to the respective voltage signal input portions. Each of the comparison portions may compare, with a reference voltage, an input voltage applied to a corresponding one of the signal transmission paths by a corresponding one of the voltage signal input portions, output a normal signal if the input voltage and the reference voltage are in a predetermined normal relationship, and output an abnormal signal if the input voltage and the reference voltage are in an abnormal relationship that is not the normal relationship. The signal distribution portion may apply a voltage with which the relationship between the input voltage and the reference voltage is in the abnormal relationship, to the signal transmission paths, which serve as input paths to the comparison portions, if the inspection instruction signal is output from the signal output portion.

In the onboard power supply device that includes a plurality of abnormality detection circuits, each of which compares an input voltage applied to a signal transmission path (a transmission path to which an abnormal voltage is applied when an abnormality has occurred at a detection target position) with a reference voltage to determine an abnormality, the failure detection device that is thus configured can cause the plurality of comparison portions to perform an operation that is to be performed in case of abnormality, with a simple configuration, and can promptly and efficiently inspect the plurality of abnormality detection circuits.

### Embodiment 1

Embodiment 1 of the present disclosure will be described below.

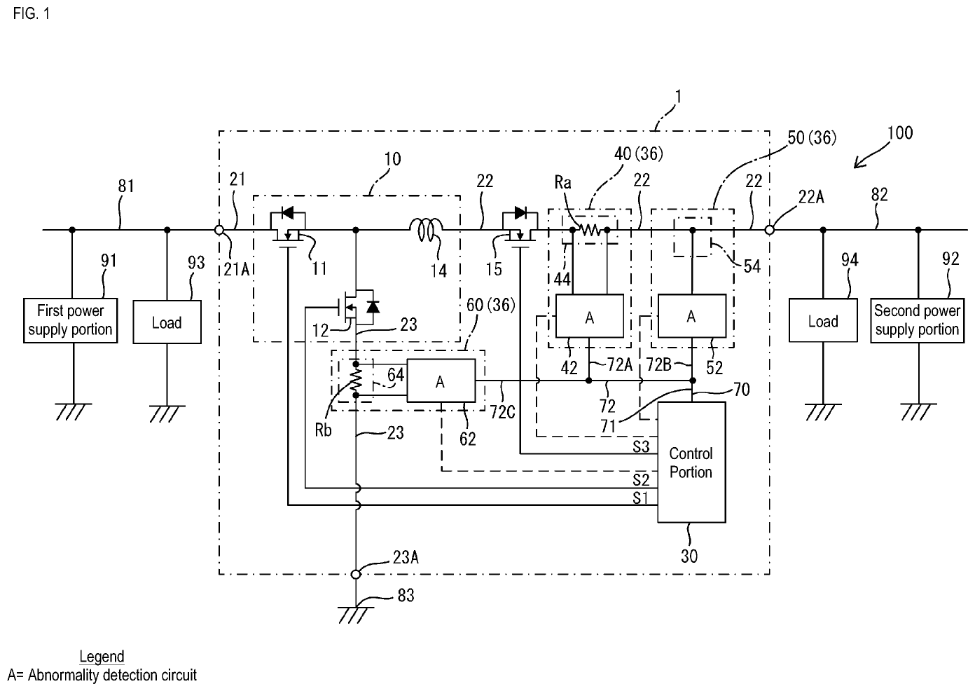

An onboard power supply system 100 shown in FIG. 1 includes a first power supply portion 91 and a second power supply portion 92, which are configured as onboard power supply portions, and an onboard power supply device 1 (hereinafter referred to also as “power supply device 1”), and is configured as a system capable of supplying electric power to loads 93 and 94 that are mounted in a vehicle. The loads 93 and 94 are onboard electrical components, and the number and type of the loads 93 and 94 are not limited.

The first power supply portion 91 is constituted by a power storage means, such as a lithium-ion battery or an electric double layer capacitor, and is for generating a first predetermined voltage. For example, the voltage at a terminal of the first power supply portion 91 on a high-potential side is kept at 48 V, and the voltage at a terminal on a low-potential side is kept at a ground potential (0 V). The terminal of the first power supply portion 91 on the high-potential side is electrically connected to a wiring portion 81, which is provided within the vehicle, and the first power supply portion 91 applies a predetermined voltage to the wiring portion 81. The terminal of the first power supply portion 91 on the low-potential side is electrically connected to a ground portion within the vehicle. The wiring portion 81 is connected to an input terminal 21A of the power supply device 1, and is electrically continuous with a first conductive path 21 via the input terminal 21A.

The second power supply portion 92 is constituted by a power storage means, such as a lead-acid battery, and is for generating a second predetermined voltage, which is lower than the first predetermined voltage generated by the first power supply portion 91. For example, the voltage at a terminal of the second power supply portion 92 on a high-potential side is kept at 12 V and the voltage at a terminal on a low-potential side is kept at a ground potential (0 V). The terminal of the second power supply portion 92 on the high-potential side is electrically connected to a wiring portion 82, which is provided within the vehicle, and the second power supply portion 92 applies a predetermined voltage to the wiring portion 82. The terminal of the second power supply portion 92 on the low-potential side is electrically connected to a ground portion within the vehicle. The wiring portion 82 is connected to an output terminal 22A of the power supply device 1, and is electrically continuous with a second conductive path 22 via the output terminal 22A.

A reference conductive path 83 is configured as a ground portion of the vehicle, and the potential in the reference conductive path 83 is kept at a fixed ground potential (0 V). The terminal of the first power supply portion 91 on the low-potential side and the terminal of the second power supply portion 92 on the low-potential side are electrically continuous with the reference conductive path 83, and a source of a later-described second element 12 is electrically connected to the reference conductive path 83 via a third conductive path 23 and a ground-side terminal 23A.

The power supply device 1 is configured as an onboard step-down DC-DC converter, which is to be mounted and used in a vehicle, and is configured to reduce a DC voltage applied to an input-side conductive path (the first conductive path 21) and output the reduced voltage to an output-side conductive path (the second conductive path 22).

The power supply device 1 mainly includes the first conductive path 21, the second conductive path 22, the third conductive path 23, a voltage conversion portion 10, a control portion 30, an abnormality detection portion 36, a signal transmission portion 70, and so on. A failure detection device 3 is constituted by the abnormality detection portion 36, the signal transmission portion 70, and the control portion 30.

The first conductive path 21 is configured as a primary (high voltage-side) power supply line to which a relatively high voltage is applied. The first conductive path 21 is configured to be electrically continuous with the terminal of the first power supply portion 91 on the high-potential side via the wiring portion 81, and a predetermined DC voltage is applied to the first conductive path 21 from the first power supply portion 91. In the configuration in FIG. 1, the input terminal 21A is provided at an end portion of the first conductive path 21, and the wiring portion 81 is electrically connected to the input terminal 21A.

The second conductive path 22 is configured as a secondary (low voltage-side) power supply line to which a relatively low voltage is applied. The second conductive path 22 is configured to be electrically continuous with the terminal of the second power supply portion 92 on the high-potential side via the wiring portion 82, and a DC voltage that is smaller than the output voltage of the first power supply portion 91 is applied to the second conductive path 22 from the second power supply portion 92. In the configuration in FIG. 1, the output terminal 22A is provided at an end portion of the second conductive path 22, and the wiring portion 82 is electrically connected to the output terminal 22A.

The voltage conversion portion 10 is connected to the first conductive path 21 and the second conductive path 22, and is for at least performing an operation to increase or reduce a voltage applied to one of the first conductive path 21 and the second conductive path 22 and output the increased/reduced voltage to the other one of the first conductive path 21 and the second conductive path 22. The following description will describe an example in which the voltage conversion portion 10 performs an operation to reduce a voltage applied to the first conductive path 21 and output the reduced voltage to the second conductive path 22.

The voltage conversion portion 10 includes a first element 11, which is provided on a high side and is configured as a semiconductor switching element that is provided between the first conductive path 21 and the second conductive path 22 and is electrically connected to the first conductive path 21, a second element 12, which is provided on a low side and is configured as a semiconductor switching element that is electrically connected between the first conductive path 21 and the reference conductive path 83 (a conductive path in which the potential is kept at a predetermined reference potential that is lower than the potential in the first conductive path 21), and an inductor 14, which is electrically connected between the first and second elements 11 and 12 and the second conductive path 22. The voltage conversion portion 10 is a main part of the step-down DC-DC converter of a switching type, and can perform a step-down operation to reduce a voltage applied to the first conductive path 21 by switching the first element 11 between an ON operation and an OFF operation and output the reduced voltage to the second conductive path 22. Although not shown in the diagrams, an input-side capacitor (not shown) is provided between the first conductive path 21 and the third conductive path 23, and an output-side capacitor (not shown) is provided between the second conductive path 22 and the third conductive path 23.

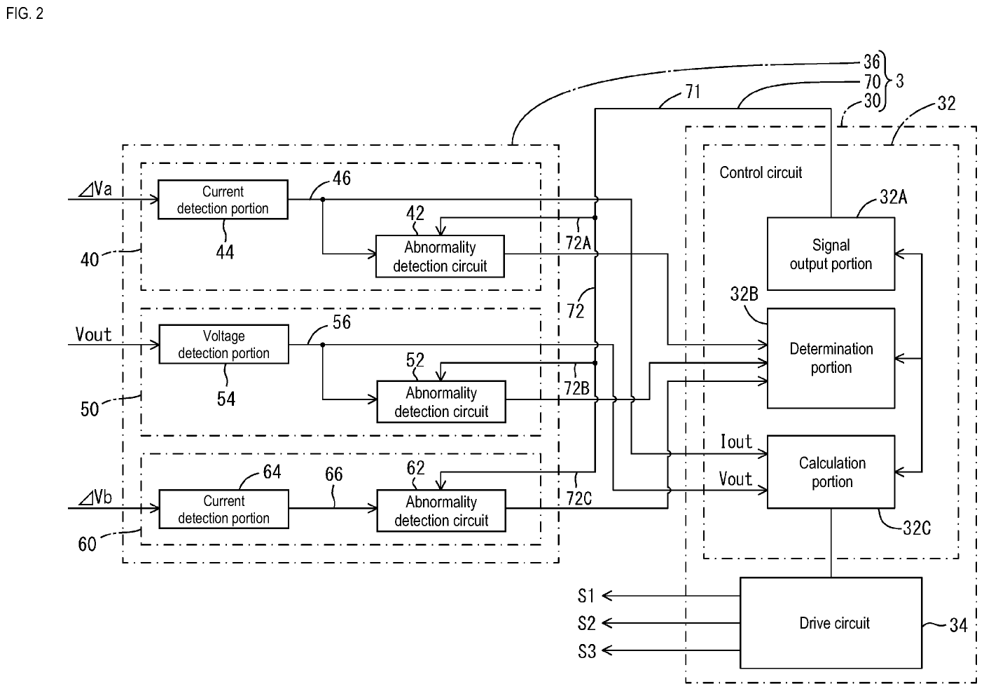

Both the first element 11 and the second element are configured as N-channel MOSFETs, and one end of the first conductive path 21 is connected to a drain of the first element 11 provided on the high side. The drain of the first element 11 is electrically connected to an electrode of the input-side capacitor (not shown) on one side and also to the terminal of the first power supply portion 91 on the high-potential side via the first conductive path 21 and the wiring portion 81, and can thus be electrically continuous with the input-side capacitor and the first power supply portion 91. A source of the first element 11 is electrically connected to a drain of the second element 12 provided on the low side and one end of the inductor 14 are electrically connected to, and can thus be electrically continuous with the second element 12 and the inductor 14. A driving signal and a non-driving signal from a drive circuit 34 (FIG. 2), which is provided in the control portion 30, are input to a gate of the first element 11, and the first element 11 switches between an on-state and an off-state in accordance with the signals from the control portion 30.

The third conductive path 23 is connected to a source of the second element 12 provided on the low side. The third conductive path 23 is a conductive path between the source of the second element 12 and the ground-side terminal 23A, and electrodes of the input-side capacitor and the output-side capacitor (which are not shown) on the other sides are electrically connected to the third conductive path 23. A driving signal and a non-driving signal from the control portion 30 are also input to the gate of the second element 12 provided on the low side, and the second element 12 switches between an on-state and an off-state in accordance with the signals from the control portion 30.

One end of the inductor 14 is connected to a connecting portion between the first element 11 and the second element 12, and is electrically connected to the source of the first element 11 and the drain of the second element 12. The other end of the inductor 14 is connected to the second conductive path 22 (specifically, a portion of the second conductive path 22 on the voltage conversion portion 10 side of a current detection portion 44).

A switching element 15 is configured as an N-channel MOSFET, and can function as a switching element for preventing a reverse current. A path on one side of the second conductive path 22 is connected to a drain of the switching element 15, and a path on the other side of the second conductive path 22 is connected to a source of the switching element 15. An ON signal and an OFF signal from the control portion 30 are input to a gate of the switching element 15, and the switching element 15 switches between an ON state and an OFF state in accordance with the signals from the control portion 30.

The abnormality detection portion 36 includes a first detection portion 40, a second detection portion 50, and a third detection portion 60, and has a function of detecting a voltage or a current at each detection target position in the power supply device 1 and determining whether or not each detection value is abnormal. For example, the abnormality detection portion 36 has a configuration shown in FIG. 2, which is schematically shown in FIG. 1. The abnormality detection circuit 36 functions such that a plurality of abnormality detection circuits 42, 52, and 62 detect abnormalities in a current or a voltage that occurs at a plurality of detection target positions.

As shown in FIG. 2, the first detection portion 40 includes a current detection portion 44 and an abnormality detection circuit 42. The current detection portion 44 functions as a voltage signal input portion and outputs a value that indicates a current Iout flowing through the second conductive path 22. Specifically, the current detection portion 44 outputs an analog voltage signal that indicates a potential difference ΔVa across a resistor portion Ra, which is provided in the second conductive path 22, or an analog voltage signal obtained by amplifying the potential difference ΔVa across the resistor portion Ra. The analog voltage signal (a voltage signal that indicates the output current Iout) output from the current detection portion 44 is applied to a signal transmission path 46, and is input to the abnormality detection circuit 42 and a control circuit 32.

The second detection portion 50 includes a voltage detection portion 54 and an abnormality detection circuit 52. The current detection portion 54 functions as a voltage signal input portion, and applies a value that indicates a voltage Vout in the second conductive path 22 to a signal transmission path 56. The voltage detection portion 54 may be any known voltage detection circuit capable of applying a value that indicates the voltage Vout in the second conductive path 22 to the signal transmission path 56, and may be, for example, configured as a voltage divider that divides the voltage in the second conductive path 22 and applies the divided voltage to the signal transmission path 56, or may be a circuit that electrically connects the second conductive path 22 to the signal transmission path 56 to establish electrical continuity therebetween.

The third detection portion 60 includes a current detection portion 64 and an abnormality detection circuit 62. The current detection portion 64 functions as a voltage signal input portion, and applies a value that indicates a current Ignd flowing through the third conductive path 23. Specifically, the current detection portion 64 outputs an analog voltage signal that indicates a potential difference ΔVb across a resistor portion Rb, which is provided in the second conductive path 22, or an analog voltage signal obtained by amplifying the potential difference ΔVb across the resistor portion Rb. The analog voltage signal (a voltage signal that indicates the current Ignd flowing between the second element 12 and the reference conductive path 83) output from the current detection portion 64 is applied to a signal transmission path 66, and is input to the abnormality detection circuit 62 and the control circuit 32.

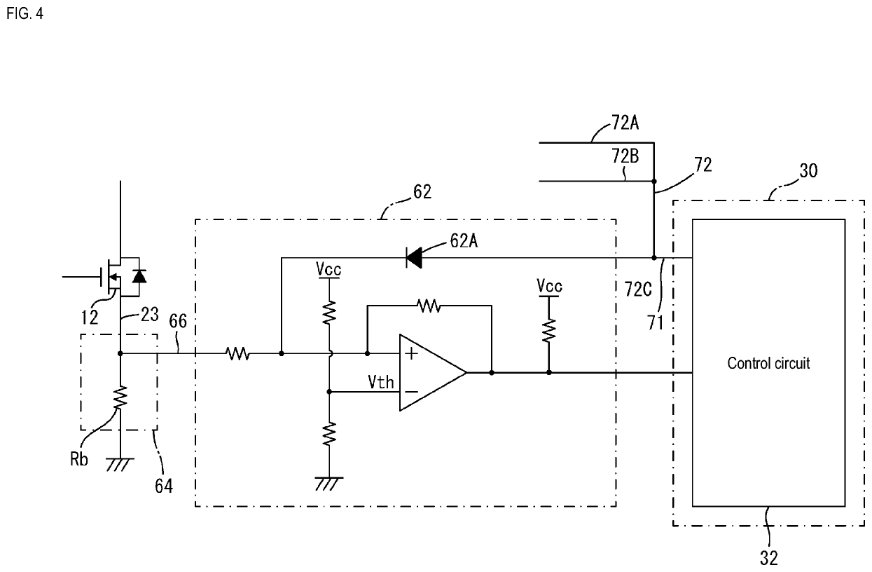

In the first detection portion 40, the second detection portion 50, and the third detection portion 60 that constitute the abnormality detection portion 36, the abnormality detection circuits 42, 52, and 62 have a configuration shown in FIG. 4, for example. Although FIG. 4 shows a configuration of the abnormality detection circuit 62 as a representative, the abnormality detection circuits 42 and 52 also have a similar configuration. The abnormality detection circuit 62 shown in FIG. 4 is configured as a comparator circuit, which outputs an abnormality detection signal if a voltage applied to the signal transmission path 66 exceeds a threshold, and does not output the abnormality detection signal if a voltage applied to the signal transmission path 66 is smaller than the threshold. Note that the abnormality detection circuit shown in FIG. 4 is merely an example, and all of the abnormality detection circuits 42, 52, and 62 need only be configured to output a predetermined abnormality detection signal if an input voltage applied to a corresponding signal transmission path exceeds a threshold, and not output the abnormality detection signal if the input voltage does not exceeds the threshold. The abnormality detection portion 36 operates to output the abnormality detection signal to the control portion 30 if any of the plurality of abnormality detection circuits 42, 52, and 62 has detected an abnormality in a current or a voltage.

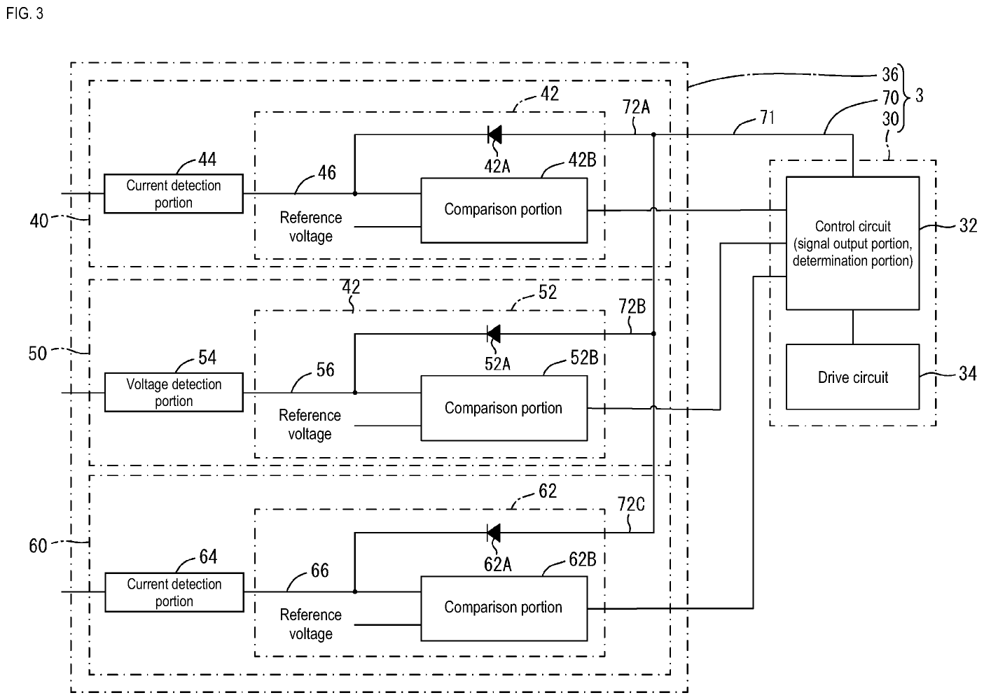

The abnormality detection circuit 42 corresponds to an example of an output current abnormality detection circuit, and detects an abnormality in a current in the second conductive path 22, which is an output-side conductive path. Specifically, as shown in FIG. 3, the abnormality detection circuit 42 compares an input voltage with a reference voltage using a comparison portion 42B, the input voltage being a voltage (a voltage corresponding to the current in the second conductive path 22) that is applied to the signal transmission path 46 from the current detection portion 44, which is a corresponding voltage signal input portion. The comparison portion 42B outputs a predetermined abnormality detection signal if the input voltage is higher than the reference voltage, and outputs a predetermined normal signal if the input voltage is smaller than or equal to the reference voltage. That is to say, the abnormality detection signal is output from the comparison portion 42B if the current flowing through the second conductive path 22 exceeds a threshold voltage.

The abnormality detection circuit 52 corresponds to an example of an output voltage abnormality detection circuit, and detects an abnormality in a voltage in the second conductive path 22, which is an output-side conductive path. Specifically, the abnormality detection circuit 52 compares an input voltage with a reference voltage using a comparison portion 52B, the input voltage being a voltage (a voltage corresponding to the voltage in the second conductive path 22) that is applied to the signal transmission path 56 from the voltage detection portion 54, which is a corresponding voltage signal input portion. The comparison portion 52B outputs a predetermined abnormality detection signal if the input voltage is higher than the reference voltage, and outputs a predetermined normal signal if the input voltage is smaller than or equal to the reference voltage. That is to say, the comparison portion 52B outputs the abnormality detection signal if the voltage at a detection position in the second conductive path 22 exceeds the threshold voltage.

The abnormality detection circuit 62 corresponds to an example of an abnormality detection circuit on the reference conductive path side, and detects an abnormality in a current flowing between the second element 12 and the reference conductive path 83. Specifically, the abnormality detection circuit 62 compares an input voltage with a reference voltage using a comparison portion 62B, the input voltage being a voltage (a voltage corresponding to a current in the third conductive path 23) that is applied to the signal transmission path 66 from the current detection portion 64, which is a corresponding voltage signal input portion. The comparison portion 62B outputs a predetermined abnormality detection signal if the input voltage is higher than the reference voltage, and outputs a predetermined normal signal if the input voltage is smaller than or equal to the reference voltage. That is to say, the comparison portion 62B outputs the abnormality detection signal if a current flowing through the third conductive path 23 exceeds a threshold voltage.

Thus, the abnormality detection circuits 42, 52, and 62 compare the input voltage, which is the voltage applied to the signal transmission paths from the corresponding voltage signal input portions, with the respective reference voltages using the comparison portions, and operate to output the abnormality detection signal if the input voltage exceeds the reference voltage, and output a normal signal if the input voltage is smaller than or equal to the reference voltage.

As shown in FIG. 2, the control portion 30 includes the control circuit 32 and the drive circuit 34, and has a function of controlling the voltage conversion portion 10. The control circuit 32 is configured as a microcomputer, for example, and includes a CPU for performing various kinds of calculation processing, a ROM for storing information such as programs, a RAM for storing temporarily generated information, an A/D converter for converting an input analog voltage to a digital value, and so on. The A/D converter is given detection signals (analog voltage signals corresponding to detected voltages) from the current detection portions 44 and 64, and detection signals (analog voltage signals corresponding to detected currents) from the voltage detection portion 54. Note that portions of the control circuit 32 that function as a signal output portion 32A, a determination portion 32B, and a calculation portion 32C may be realized by software processing in the microcomputer, or may be realized by a hardware circuit.

When causing the voltage conversion portion 10 to perform a step-down operation, the control circuit 32 performs feedback calculation so as to bring the voltage to be applied to the second conductive path 22 close to a set target value while detecting the voltage Vout in the second conductive path 22 using the voltage detection portion 54, and generates a PWM signal. Specifically, a portion of the control circuit 32 that functions as the calculation portion 32C repeats the feedback calculation at short time intervals while monitoring the voltage Vout in the second conductive path 22 that is detected by the voltage detection portion 54. The calculation portion 32C adjusts the duty cycle to increases the duty cycle through the feedback calculation such that the voltage in the second conductive path 22 detected by the voltage detection portion 54 approaches the target value if the voltage is smaller than the target value, and to reduce the duty cycle through the feedback calculation such that the voltage approaches the target value if the voltage is greater than the target value.

The drive circuit 34 applies an ON signal for alternately turning on the first element 11 and the second element 12 in respective control cycles to the gates of the first element 11 and the second element 12, based on the PWM signal given from the control circuit 32. The phase of the ON signal applied to the gate of the first element 11 is substantially inverted relative to the phase of the ON signal given to the gate of the second element 12, and a so-called dead time is secured in the ON signal applied to the gate of the first element 11.

The power supply device 1 that is thus configured above functions as a step-down DC-DC converter of a synchronously rectifying type, reduces a DC voltage applied to the first conductive path 21 by switching the second element 12 provided on the low side between the ON operation and the OFF operation synchronously with the operation of the first element 11 provided on the high side, and outputs the reduced DC voltage to the second conductive path 22. Specifically, a first state where the first element 11 is in the ON state and the second element 12 is in the OFF state and a second state where the first element 11 is in the OFF state and the second element 12 is in the ON state are alternately switched by the control of the control portion 30. The DC voltage applied to the first conductive path 21 is reduced by repeatedly switching between the first state and the second state, and is output to the second conductive path 22. The output voltage of the second conductive path 22 is determined in accordance with the duty cycle of the PWM signal that is given to the gate of the first element 11. Note that FIGS. 1 and 2 schematically show the signal to be given to the gate of the first element 11 as 51, and schematically show the signal to be given to the gate of the second element 12 as S2.

The control circuit 32 determines whether or not the state of a current flowing through the second conductive path 22 is in a reverse current state based on a detection value output from the current detection portion 44. The normal state of a current flowing through the second conductive path 22 is a state where the current flows from the source side toward the drain side of the switching element 15, and the reverse current state is a state where the current flows from the drain side toward the source side of the switching element 15. The control circuit 32 drives the voltage conversion portion 10 while keeping the switching element 15 in the ON state, for example, and if the reverse current state has occurred in the second conductive path 22 while the control circuit 32 is driving the voltage conversion portion 10, the control circuit 32 performs a protection operation to switch the switching element 15 to the OFF state. Note that FIGS. 1 and 2 schematically show the signal to be given to the gate of the switching element 15 as S3.

Basic control performed by the control portion 30 will now be described.

The control portion 30 of the power supply device 1 drives the voltage conversion portion 10 to cause the voltage conversion portion 10 to perform a voltage converting operation if a predetermined start condition holds. Specifically, for example, an ignition-on signal is given from an external device to the control portion 30 if an ignition switch is in an ON state, and an ignition-off signal is given from the external device to the control portion 30 if the ignition switch is in an OFF state. The control portion 30 gives a control signal to the voltage conversion portion 10 under a start condition that the ignition switch has switched from the OFF state to the ON state, and causes the voltage conversion portion 10 to perform the voltage converting operation, for example. Specifically, the control portion 30 causes the voltage conversion portion 10 to perform a step-down operation while repeating the feedback calculation to adjust the duty cycle of the PWM signal such that the voltage in the second conductive path 22 is a desired target voltage (a predetermined voltage value that is greater than the voltage in the reference conductive path 83; e.g. a value that is slightly greater than the output voltage of the second power supply portion 92 that is fully charged), based on the voltage in the second conductive path 22 that is monitored by the voltage detection portion 54.

Next, the abnormality detection control performed by the control portion 30 will be described.

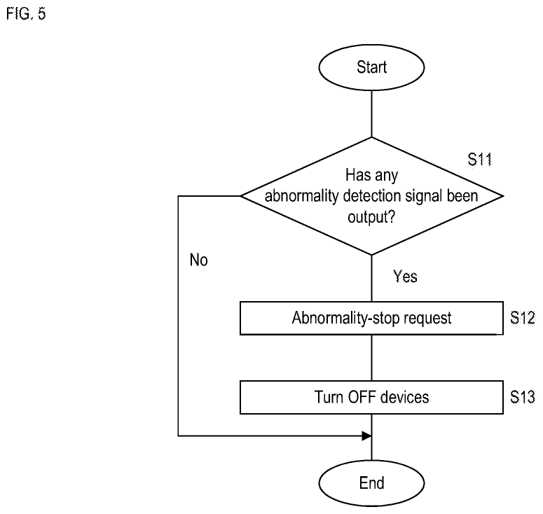

The control portion 30 repeatedly performs the abnormality detection control shown in FIG. 5, while performing the above-described basic control. When the abnormality detection control is performed, initially, in step S11, the control circuit 32 determines whether or not the abnormality detection signal has been output from any of the abnormality detection circuits 42, 52, and 62. If no abnormality detection signal has been output from any of the abnormality detection circuits 42, 52, and 62 (No in step S11), the control circuit 32 ends the abnormality detection control in FIG. 5 and then repeats the abnormality detection control in FIG. 5 so as to immediately start again the abnormality detection control. If the abnormality detection signal has been output from any of the abnormality detection circuits 42, 52, and 62 (Yes in step S11), the control circuit 32 makes an abnormality-stop request to the drive circuit 34 (step S12). In step S13 that follows step S12, the drive circuit 34 that has received the abnormality-stop request sets all of the signals 51, S2, and S3 that are to be given to the first element 11, the second element 12, and the switching element 15, respectively, as OFF signals to stop the operation of the voltage conversion portion 10. Thus, if an abnormality has been detected by any of the abnormality detection circuits 42, 52, and 62 and the abnormality detection signal has been output, the first element 11, the second element 12, and the switching element 15 can be turned off to stop the voltage conversion portion 10.

Operations of the failure detection device 3 will now be described.

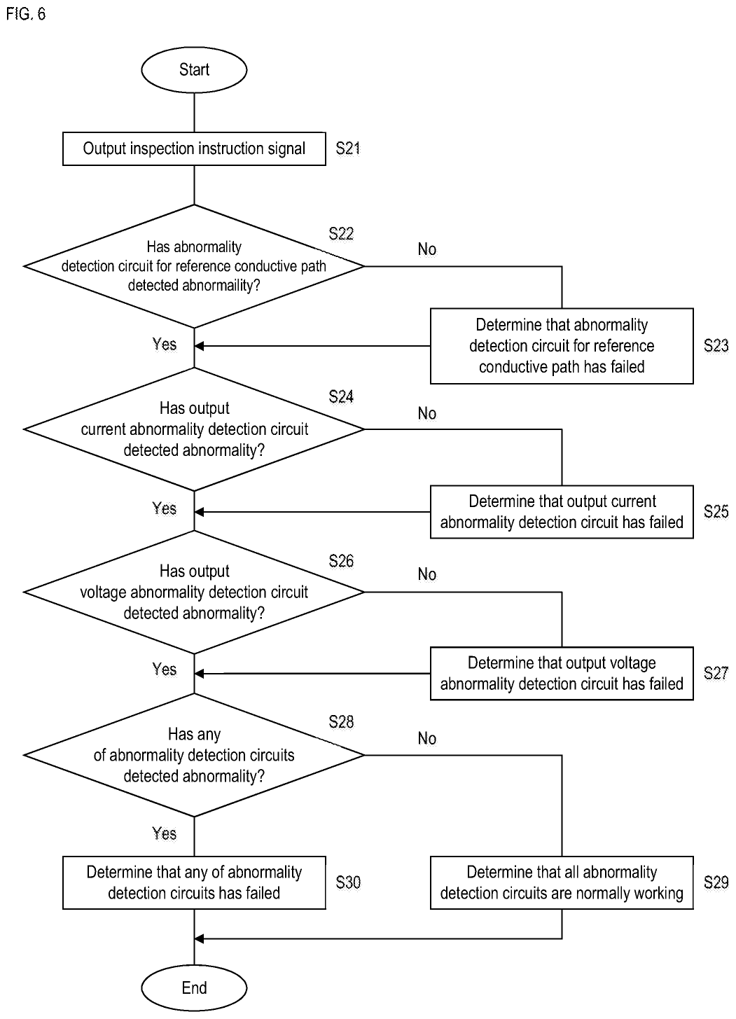

As shown in FIG. 2, the failure detection circuit 3 includes the abnormality detection portion 36, which includes the plurality of abnormality detection circuits 42, 52, and 62, the control portion 30, and the signal transmission portion 70. The failure detection device 3 performs failure detection control, which is mainly performed by the control portion 30, according to a flow shown in FIG. 6.

The control portion 30 is configured to be able to not only perform the above-described basic control and abnormality detection control, but also performs the failure detection control shown in FIG. 6 at a predetermined inspection time and operates to determine whether or not the abnormality detection circuits 42, 52, and 62 have failed. Although various examples of the predetermined inspection time are conceivable, for example, the predetermined inspection time may be immediately after the ignition switch has switched from the OFF state to the ON state, or may be immediately after the ignition switch has switched from the ON state to the OFF state. Alternately, the predetermined inspection time may be a predetermined timing while the control portion 30 is performing the aforementioned basic control.

If the control in FIG. 6 has been started in accordance with the arrival of the inspection time, initially, the control portion 30 performs processing in step S21. Specifically, a portion of the control portion 30 that functions as the signal output portion 32A operates to output, via a shared signal line 71, an inspection instruction signal for instructing the plurality of abnormality detection circuits 42, 52, and 62 to perform an operation that is to be performed in case of abnormality, when performing the processing in step S21. The inspection instruction signal is a high-level signal of a predetermined voltage, for example. The voltage of the inspection instruction signal output from the signal output portion 32A is a voltage that is lower than the output voltages of the first power supply portion 91 and the second power supply portion 92, and is higher than respective reference voltages used at the comparison portions 42B, 52B, and 62B, for example. Note that, in a period other than the inspection time, the signal output portion 32A keeps the voltage to be applied to the shared signal line 71 at a predetermined low level (e.g. a voltage value that is significantly lower than the respective reference voltages used at the comparison portions 42B, 52B, and 62B).

Upon the signal output portion 32A outputting the inspection instruction signal to the shared signal line 71, the signal transmission portion 70 transmits this inspection instruction signal to the abnormality detection circuits 42, 52, and 62. The signal transmission portion 70 includes the shared signal line 71 and a signal distribution portion 72 that is connected to the shared signal line. The signal distribution portion 72 has a plurality of branch signal lines 72A, 72B, and 72C, which branch from the shared signal line 71, and distributes the inspection instruction signal output from the control portion 30 (signal output portion 32A) to the shared signal line 71 to the abnormality detection circuit 42 (output current abnormality detection circuit), the abnormality detection circuit 52 (output voltage abnormality detection circuit), and the abnormality detection circuit 62 (abnormality detection circuit on the reference conductive path side) through the plurality of branch signal lines 72A, 72B, and 72C. Note that the branch signal lines 72A, 72B, and 72C are provided with diodes 42A, 52A, and 62A, respectively, respectively, such that no current flows from the signal transmission paths 46, 56, and 66 toward the shared signal line 71 side.

When the power supply device 1 is operating normally, the reference voltages used at the respective comparison portions 42B, 52B, and 62B are set to values that are higher than the voltages that are to be applied to the respective signal transmission paths 46, 56, and 66 and to be compared when the power supply device 1 is operating normally. Also, the reference voltages used at the respective comparison portions 42B, 52B, and 62B are set to values that are lower than the voltages in the respective signal transmission paths 46, 56, and 66 that are to be compared when the inspection instruction signal has been output from the control portion 30 (signal output portion 32A) in the case where the output from any of the current detection portion 44, the voltage detection portion 54, and the current detection portion 64 is smaller than the reference voltage. That is to say, if the inspection instruction signal has been applied to the shared signal line 71, the signal distribution portion 72 distributes the inspection instruction signal so as to apply a voltage greater than the reference voltages, which are to be compared with the respective voltages, to the signal transmission paths 46, 56, and 66.

Due to this configuration, when the control portion 30 (signal output portion 32A) has output the inspection instruction signal to the shared signal line 71, a voltage that exceeds the respective reference voltages is applied to the signal transmission paths 46, 56, and 66, and the abnormality detection signal is output from each of the abnormality detection circuits 42, 52, and 62 if the abnormality detection circuits 42, 52, and 62 has not failed and operates normally.

After the signal output portion 32A has output the inspection instruction signal in step S21, in step S22, the portion of the control portion 30 that functions as the determination portion 32B determines whether or not the abnormality detection circuit 62 (the abnormality detection circuit on the reference conductive path side) has detected an abnormality, i.e. whether or not the abnormality detection signal has been output from the abnormality detection circuit 62. If the determination portion 32B determines in step S22 that no abnormality detection signal has been output from the abnormality detection circuit 62, in step S23, the determination portion 32B determines that the abnormality detection circuit 62 (abnormality detection circuit on the reference conductive path side) has failed.

If the determination portion 32B has determined in step S22 that the abnormality detection signal has been output from the abnormality detection circuit 62 (Yes in step S22), in step S24, the determination portion 32B determines whether or not the abnormality detection circuit 42 (output current abnormality detection circuit) has detected an abnormality, i.e. whether or not the abnormality detection signal has been output from the abnormality detection circuit 42. If the determination portion 32B has determined in step S24 that no abnormality detection signal has been output from the abnormality detection circuit 42, in step S25, the determination portion 32B determines that the abnormality detection circuit 42 (output current abnormality detection circuit) has failed.

If the determination portion 32B has determined in step S24 that the abnormality detection signal has been output from the abnormality detection circuit 42 (Yes in step S24), in step S26, the determination portion 32B determines whether or not the abnormality detection circuit 52 (output voltage abnormality detection circuit) has detected an abnormality, i.e. whether or not the abnormality detection signal has been output from the abnormality detection circuit 52. If the determination portion 32B has determined in step S26 that no abnormality detection signal has been output from the abnormality detection circuit 52, in step S27, the determination portion 32B determines that the abnormality detection circuit 52 (output voltage abnormality detection circuit) has failed.

If the result in step S26 is Yes, or after step S27, in step S28, the determination portion 32B determines whether or not any of the abnormality detection circuits 42, 52, and 62 has detected an abnormality. If the determination portion 32B has determined in step S28 that any of the abnormality detection circuits has detected an abnormality, i.e. if the determination portion 32B has made any of the determinations in steps S23, S25, and S27, in step S30, the determination portion 32B determines that any of the abnormality detection circuits has failed. On the other hand, if none of the abnormality detection circuits 42, 52, and 62 has detected an abnormality, i.e. if the determination portion 32B has not made any of the determinations in steps S23, S25, and S27, in step S29, the determination portion 32B determines that all of the abnormality detection circuits are normally working. Note that, if the determination portion 32B has made the determination in step S30, the determination portion 32B may also transmit, to an external ECU or the like, information indicating that a failure of any of the abnormality detection circuits has occurred, and may also perform any other error handling operations (error notification by means of a lamp, sound, etc.).

Thus, according to the present configuration, at least a portion of the control circuit 32 functions as the determination portion 32B, and determines whether or not each of the abnormality detection circuits 42, 52, and 62 has failed, based on the signals output from the plurality of abnormality detection circuits 42, 52, and 62 when the signal output portion 32A has output the inspection instruction signal via the shared signal line 71.

Examples of the effects of the present configuration will be described below.

In the above-described failure detection device 3, at least a portion of the control circuit 32 functions as the signal output portion 32A, and outputs, via the shared signal line 71, an inspection instruction signal (a signal for instructing the plurality of abnormality detection circuits 42, 52, and 62 to perform the operation that is to be performed in case of abnormality). The signal distribution portion 72 then transmits the inspection instruction signal output from the control circuit 32 to the shared signal line 71 to the abnormality detection circuits 42, 52 and 62 through the plurality of branch signal lines 72A, 72B, and 72C. Due to the above-described configuration, the plurality of abnormality detection circuits 42, 52, and 62 can be caused to perform the operation that is to be performed in case of abnormality, even when no abnormality has actually occurred at the respective detection target positions of the abnormality detection circuits 42, 52, and 62. Furthermore, at least a portion of the control circuit 32 can function as the determination portion 32B, and determine whether or not each of the abnormality detection circuits 42, 52, and 62 has failed, based on the signals output from the plurality of abnormality detection circuits 42, 52, and 62 when the inspection instruction signal is output. Moreover, the plurality of abnormality detection circuits 42, 52, and 62 can be simultaneously instructed to perform the operation that is to be performed in case of abnormality, and these abnormality detection circuits 42, 52, and 62 can be caused to promptly perform the operation for inspection. Thus, whether or not at least one of the plurality of abnormality detection circuits has failed can be determined in a shorter time.

The abnormality detection portion 36 includes, as a plurality of abnormality detection circuits, the abnormality detection circuit 42, which serves as the output current abnormality detection circuit for detecting an abnormality in a current in a conductive path (second conductive path 22) on the output side of the voltage conversion portion 10, and the abnormality detection circuit 52, which serves as the output voltage abnormality detection circuit for detecting an abnormality in a voltage in the output-side conductive path. The signal distribution portion 72 is configured to distribute an inspection instruction signal output from the control circuit 32, which corresponds to the signal output portion, to the shared signal line 71 at least to the output current abnormality detection circuit (abnormality detection circuit 42) and the output voltage abnormality detection circuit (abnormality detection circuit 52).

The failure detection device 3 that is thus configured can simultaneously inspect the output current abnormality detection circuit (abnormality detection circuit 42) for detecting an abnormality in a current in the output-side conductive path (second conductive path 22), and the output voltage abnormality detection circuit (abnormality detection circuit 52) for detecting an abnormality in a voltage in the output-side conductive path, and can determine, in a shorter time, whether or not a failure has occurred in either one of the abnormality detection circuits 42 and 52 that can detect abnormalities at critical positions.

The voltage conversion portion 10 includes the first element 11, which is constituted by a switching element that is electrically connected to the first conductive path 21, the second element 12, which is constituted by a switching element that is electrically connected between the first conductive path 21 and the reference conductive path 83 whose potential is kept at a predetermined reference potential that is lower than the potential in the first conductive path 21, and the inductor 14, which is electrically connected between the first and second elements 11 and 12 and the second conductive path 22. The abnormality detection portion 36 includes the abnormality detection circuit on the reference conductive path side (abnormality detection circuit 62) for detecting an abnormality in a current flowing between the second element 12 and the reference conductive path 83. The signal distribution portion 72 is configured to distribute the inspection instruction signal that is output to the shared signal line 71 from the control circuit 32, which corresponds to the signal output portion, at least to the abnormality detection circuit on the reference conductive path side (abnormality detection circuit 62).

The failure detection device 3 that is thus configured can simultaneously inspect the abnormality detection circuit on the reference conductive path side (abnormality detection circuit 62) together with the other abnormality detection circuits, and can determine, in a shorter time, whether or not a failure has occurred in the abnormality detection circuit 62 that can detect an abnormality at a critical position.

The abnormality detection portion 36 includes a plurality of signal transmission paths 46, 56, and 66, which correspond to a plurality of respective detection target positions, a plurality of voltage signal input portions (current detection portion 44, voltage detection portion 54, and current detection portion 64) that applies voltage signals corresponding to a voltage or a current at the respective detection target positions to the respective signal transmission paths 46, 56, and 66, and a plurality of comparison portions 42B, 52B, and 62B that correspond to the respective voltage signal input portions. Each of the comparison portions 42B, 52B, and 62B compares the input voltage that is applied to a corresponding one of the signal transmission paths 46, 56, and 66 by a corresponding one of the voltage signal input portions (current detection portion 44, voltage detection portion 54, and current detection portion 64) with the reference voltage, outputs a normal signal if the input voltage and the reference voltage are in a predetermined normal relationship, and outputs an abnormal signal if the input voltage and the reference voltage are in an abnormal relationship that is not the normal relationship. If the inspection instruction signal is output from the control circuit 32, which corresponds to the signal output portion, the signal distribution portion 72 applies a voltage with which the relationship between the input voltage and the reference voltage are in an abnormal relationship to the signal transmission paths 46, 56, and 66, which are input paths to the respective comparison portions 42B, 52B, and 62B.

In the onboard power supply device 1 that is provided with the plurality of abnormality detection circuits, each of which compares an input voltage applied to a corresponding signal transmission path (a transmission path to which an abnormal voltage is applied when an abnormality occurs at a detection target position) with a reference voltage to determine an abnormality, the failure detection device 3 that is configured as described above can cause the plurality of comparison portions 42B, 52B, and 62B to perform the operation that is to be performed in case of abnormality, with a simple configuration, and can promptly and efficiently inspect the plurality of abnormality detection circuits 42, 52, and 62.

### Embodiment 2

Next, Embodiment 2 will be described.

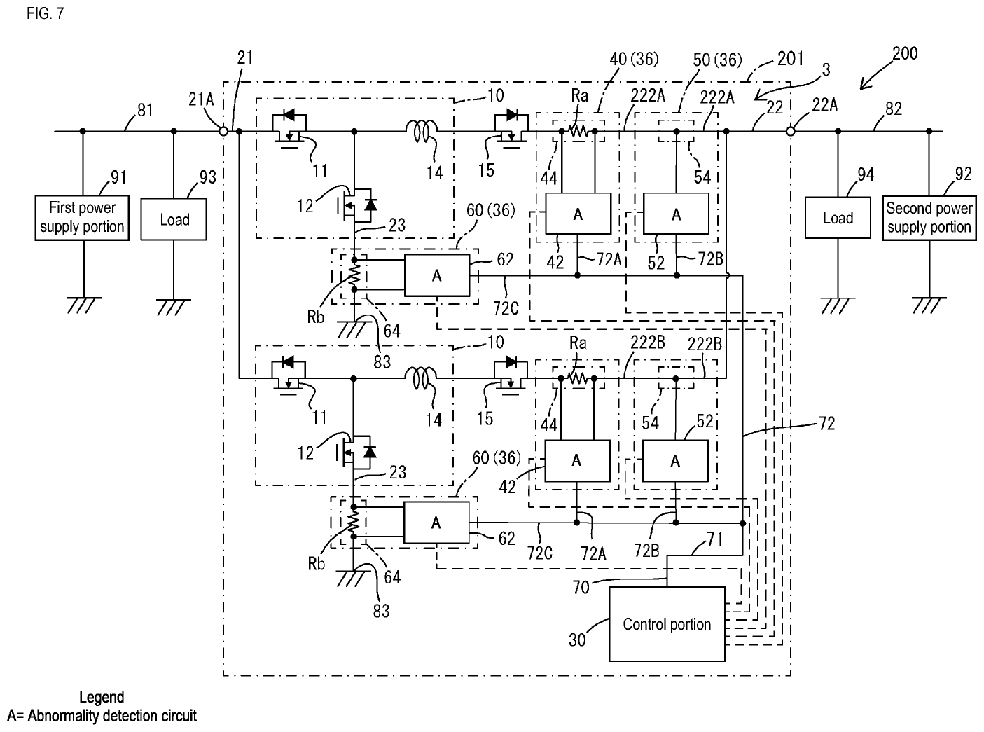

An onboard power supply system 200 shown in FIG. 7 differs from the onboard power supply system 100 shown in FIG. 1 only by the power supply device 201. The power supply device 201 according to Embodiment 2 differs, in terms of the circuit configuration, from the power supply device 1 according to Embodiment 1 only in that a plurality of voltage conversion portions 10 are provided between the first conductive path 21 and the second conductive path 22, and the other circuit configuration is similar to that in Embodiment 1. Note that FIG. 7 omits signal lines connected to the switching elements (the first element 11, the second element 12, and the switching element 15) from the control portion 30.

In the power supply device 20 shown in FIG. 7, a plurality of voltage conversion portions 10, in each of which the first element 11, the second element 12, and the inductor 14 are provided, and the voltage conversion portions 10 are provided in parallel between the first conductive path 21 and the second conductive path 22. Each of the voltage conversion portions 10 has a configuration similar to that in Embodiment 1. The third conductive paths 23 of all of the voltage conversion portions 10 are electrically connected to the reference conductive path 83, which is configured as a ground portion, and a current flows between the third conductive paths 23 and the ground portion.

In the power supply device 201, the first detection portion 40 and the second detection portion 50, which are similar to those in Embodiment 1, are provided in output-side conductive paths 222A and 222B of the respective voltage conversion portions 10. The first detection portion 40 and the second detection portion 50 have a configuration similar to that of the first detection portion 40 and the second detection portion 50 (FIGS. 2 and 3), respectively, in Embodiment 1, and operates similarly to these detection portions. The third detection portion 60, which is similar to that in Embodiment 1, is provided in the third conductive path 23 of the respective voltage conversion portions 10. The third detection portion 60 is configured similarly to the third detection portion 60 in Embodiment 1, and operates similarly thereto.

Thus, the abnormality detection circuit 36 is provided with the first detection portion 40, the second detection portion 50, and the third detection portion 60 in association with the respective voltage conversion portions 10, and is provided with the plurality of abnormality detection circuits 42, 52, and 62 in association with the respective voltage conversion portion 10. In this configuration as well, the shared signal line 71 is connected to the control portion 30, and a plurality of branch signal lines branch from the shared signal line 71. Specifically, a plurality of sets of the branch signal lines 72A, 72B, and 72C, which are connected to the abnormality detection circuits 42, 52, and 62, respectively, are provided in association with the respective voltage conversion portions 10. In this configuration as well, at least a portion of a control circuit (which is a circuit similar to the control circuit 32 in FIGS. 2 and 3) in the control portion 30 functions similarly to the signal output portion 32A (FIG. 2), and outputs an inspection instruction signal (which is a signal for instructing the plurality of abnormality detection circuits to perform the operation that is to be performed in case of abnormality) similar to that in Embodiment 1 via the shared signal line 71. The signal distribution portion 72 is configured to distribute the inspection instruction signal that is output to the shared signal line 71 from the control circuit (which is a circuit similar to the control circuit 32 in FIGS. 2 and 3) in the control portion 30, which corresponds to the signal output portion, to the abnormality detection circuits 42, 52, and 62 that are associated with the respective voltage conversion portions 10. Also, in this configuration as well, at least a portion of the control circuit (which is a circuit similar to the control circuit 32 in FIGS. 2 and 3) in the control portion 30 functions similarly to the determination portion 32B (FIG. 2), and determines whether or not each of the abnormality detection circuits has failed, using a method similar to that in Embodiment 1, based ON signals that are output from the plurality of abnormality detection circuits (the plurality of abnormality detection circuits 42, 52, and 62 that correspond to the respective voltage conversion portions 10) when the control circuit has output the inspection instruction signal via the shared signal line. Thus, in this configuration as well, the failure detection device 3 is configured to include the abnormality detection portion 36, the signal transmission portion 70, and the control portion 30.

The failure detection device 3 that is thus configured can simultaneously inspect the plurality of abnormality detection circuits 42, 52, and 62 that are associated with the respective voltage conversion portions 10 in the onboard power supply device 1 that includes the plurality of voltage conversion portions 10 and is configured as a multi-phase type, and can determine, in a shorter time, whether or not a failure has occurred in the abnormality detection circuits 42, 52, and 62 even in the power supply device 1 of the multi-phase type in which the number of abnormality detection circuits 42, 52, and 62 tends to increase.

### OTHER EMBODIMENTS

The present disclosure is not limited to the embodiments that have been described in the above description and drawings, and for example, the following embodiments are also encompassed in the technical scope of the present disclosure. The above embodiments and later-described embodiments can be combined provided there is no inconsistency.

Embodiments 1 and 2 have described, as an example a configuration in which the second power supply portion 92 is electrically connected to the second conductive path 22. However, in Embodiments 1 and 2 and any examples in which Embodiments 1 and 2 are modified, the second power supply portion 92 does not need to be electrically connected to the second conductive path 22. Alternatively, the first power supply portion 91 does not need to be electrically connected to the first conductive path 21.

Embodiments 1 and 2 have described, as an example, a step-down DC-DC converter of a synchronously rectifying type in which the second element 12 is configured as a switching element. However, in Embodiments 1 and 2 and any examples in which Embodiments 1 and 2 are modified, a step-down DC-DC converter of a diode type in which the second element is configured as a diode (a diode with a cathode connected on the first element side and an anode connected on the reference conductive path side).

Embodiments 1 and 2 have described, as an example, the voltage conversion portion 10 that performs an operation to reduce the voltage applied to the first conductive path 21 and output the reduced voltage to the second conductive path 22. However, in Embodiments 1 and 2 and any examples in which Embodiments 1 and 2 are modified, the voltage conversion portion 10 may be a step-up DCDC converter that performs an operation to increase the voltage applied to the first conductive path 21 and output the increased voltage to the second conductive path 22, or an operation to increase the voltage applied to the second conductive path 22 and output the increased voltage to the first conductive path 21. Alternatively, the voltage conversion portion 10 may be a bidirectional DC-DC converter that can perform an operation to increase or reduce the voltage applied to the first conductive path 21 and output the increased/reduced voltage to the second conductive path 22, and an operation to increase or reduce the voltage applied to the second conductive path 22 and output the increased/reduced voltage to the first conductive path 21. In the case where the voltage conversion portion is a DC-DC converter of any type, the abnormality detection circuit (a circuit similar to the abnormality detection circuit 62 shown in FIG. 4) for detecting an abnormality in a current or a voltage can be provided at a plurality of positions, and can simultaneously check whether or not any abnormality detection circuit has failed, using a method similar to that in the above-described embodiments.

In Embodiments 1 and 2, each of the comparison portions 42B, 52B, and 62B provided in the abnormality detection circuits 42, 52, and 62, respectively, is configured to compare the input voltage applied to the corresponding signal transmission path with the reference voltage, regard a relationship in which the input voltage is smaller than or equal to the reference voltage is a predetermined normal relationship, regard a relationship in which the input voltage is greater than the reference voltage is an abnormal relationship, and output the abnormality detection signal if the input voltage is greater than the reference voltage. However, Embodiments 1 and 2 and any examples in which Embodiments 1 and 2 are modified may alternatively employ a configuration in which a relationship in which the input voltage is greater than the reference voltage and the difference between the input voltage and the reference voltage is greater than or equal to a predetermined value is regarded as an abnormal relationship, a relationship in in other cases is regarded as a normal relationship, and the abnormality detection signal is output if an abnormal relationship holds.

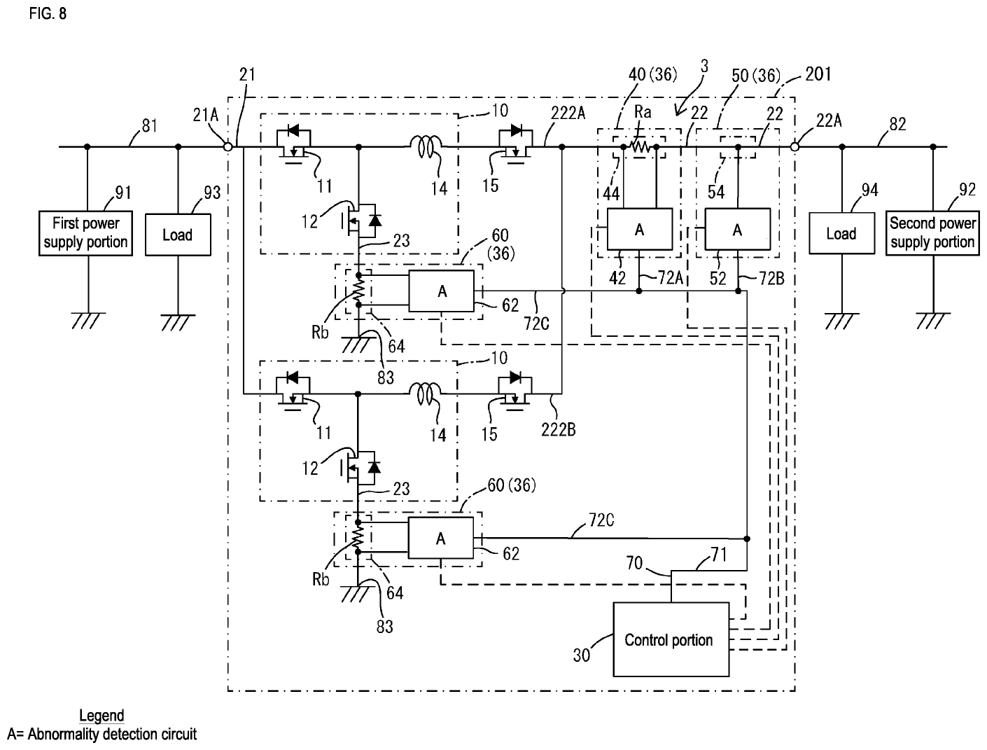

Embodiment 2 has described an example in which, in the power supply device 201 of the multi-phase type, the first detection portion 40 and the second detection portion 50 that are similar to those in Embodiment 1 are provided in the output-side conductive paths 222A and 222B of the respective voltage conversion portions 10. However, the multi-phase configuration is not limited to this example. For example, the first detection portion 40 and the second detection portion 50 similar to those in Embodiment 1 may alternatively be provided in a shared output-side conductive path (the second conductive path 22) through which currents from both the output-side conductive paths 222A and 222B flow, as shown in FIG. 8, rather than in the output-side conductive paths 222A and 222B of the respective voltage conversion portions 10. These operate similarly to the first detection portion 40 and the second detection portion 50 (FIGS. 2 and 3) in Embodiment 1. Note that third detection portions 60 similar to the third detection portion 60 in Embodiment 1 are provided in the third conductive paths 23 of the respective voltage conversion portions 10. These third detection portions 60 are configured similarly to the third detection portion 60 in Embodiment 1, and operate similarly thereto.

In this configuration as well, at least a portion of the control circuit (which is a circuit similar to the control circuit 32 in FIGS. 2 and 3) functions similarly to the signal output portion 32A (FIG. 2), and outputs an inspection instruction signal (which is a signal for instructing the plurality of abnormality detection circuits to perform the operation that is to be performed in case of abnormality) similar to that in Embodiment 1 via the shared signal line 71. The signal distribution portion 72 is configured to distribute the inspection instruction signal that is output to the shared signal line 71 from the control circuit (which is a circuit similar to the control circuit 32 in FIGS. 2 and 3) in the control portion 30, which corresponds to the signal output portion, to the abnormality detection circuits 42, 52, and 62 that are associated with the respective voltage conversion portions 10. Also, in this configuration as well, at least a portion of the control circuit (which is a circuit similar to the control circuit 32 in FIGS. 2 and 3) in the control portion 30 functions similarly to the determination portion 32B (FIG. 2), and determines whether or not each of the abnormality detection circuits has failed, using a method similar to that in Embodiment 1, based ON signals that are output from the plurality of abnormality detection circuits (the plurality of abnormality detection circuits 42, 52, and 62 that correspond to the respective voltage conversion portions 10) when the control circuit has output the inspection instruction signal via the shared signal line.

According to this configuration, in the power supply device of the multi-phase type in which the number of components tends to increase, a failure detection device can be realized that can determine, in a shorter time, whether or not a failure has occurred in at least one of the plurality of abnormality detection portions, while reducing the number of components and reducing costs.

1. A failure detection device for detecting a failure in an onboard power supply device that includes: a voltage conversion portion that is connected to a first conductive path and a second conductive path, and at least performs an operation to increase or reduce a voltage applied to one of the first conductive path and the second conductive path and output the increased or reduced voltage to the other one of the first conductive path and the second conductive path; a control portion for controlling the voltage conversion portion; and an abnormality detection portion that includes a plurality of abnormality detection circuits for detecting an abnormality in a current or a voltage occurring at a plurality of detection target positions, and outputs an abnormality detection signal if any of the abnormality detection circuits has detected an abnormality in a current or a voltage,
the failure detection device comprising:
a signal output portion for outputting, via a shared signal line, an inspection instruction signal for instructing the abnormality detection circuits to perform an operation that is to be performed in case of abnormality;
a signal distribution portion that includes a plurality of branch signal lines branching from the shared signal line, and transmits the inspection instruction signal output from the signal output portion to the shared signal line to the abnormality detection circuits through the respective branch signal lines; and
a determination portion for determining whether or not each of the abnormality detection circuits has failed, based on a signal output from each of the abnormality detection circuits when the signal output portion has output the inspection instruction signal via the shared signal line.

2. The failure detection device for the onboard power supply device according to claim 1,
wherein the abnormality detection portion includes, as the plurality of abnormality detection circuits, an output current abnormality detection circuit for detecting an abnormality in a current in a conductive path on an output side of the voltage conversion portion, and an output voltage abnormality detection circuit for detecting an abnormality in a voltage in the conductive path on the output side, and
the signal distribution portion distributes the inspection instruction signal output from the signal output portion to the shared signal line at least to the output current abnormality detection circuit and the output voltage abnormality detection circuit.

3. The failure detection device for the onboard power supply device according to claim 1,
wherein the voltage conversion portion includes a first element constituted by a switching element that is electrically connected to the first conductive path, a second element constituted by a switching element or a diode that is electrically connected between the first conductive path and a reference conductive path whose potential is kept at a predetermined reference potential that is lower than a potential in the first conductive path, and an inductor that is electrically connected between the first and second elements and the second conductive path,
the abnormality detection portion includes, as one of the abnormality detection circuits, an abnormality detection circuit on a reference conductive path side for detecting an abnormality in a current flowing between the second element and the reference conductive path, and
the signal distribution portion distributes the inspection instruction signal output from the signal output portion to the shared signal line at least to the abnormality detection circuit on the reference conductive path side.

4. The failure detection device for the onboard power supply device according to claim 1,
wherein the onboard power supply device is provided with a plurality of the voltage conversion portions,
the abnormality detection portion is provided with one or more abnormality detection circuits in association with the respective voltage conversion portions, and
the signal distribution portion distributes the inspection instruction signal output from the signal output portion to the shared signal line to the abnormality detection circuits associated with the respective voltage conversion portions.

5. The failure detection device for the onboard power supply device according to claim 1,
wherein the abnormality detection portion includes:
a plurality of signal transmission paths corresponding to the respective detection target positions;
a plurality of voltage signal input portions for applying voltage signals each corresponding to a voltage or a current at a corresponding one of the detection target positions to the respective signal transmission paths; and
a plurality of comparison portions corresponding to the respective voltage signal input portions,
each of the comparison portions compares, with a reference voltage, an input voltage applied to a corresponding one of the signal transmission paths by a corresponding one of the voltage signal input portions, outputs a normal signal if the input voltage and the reference voltage are in a predetermined normal relationship, and outputs an abnormal signal if the input voltage and the reference voltage are in an abnormal relationship that is not the normal relationship, and
the signal distribution portion applies a voltage with which the relationship between the input voltage and the reference voltage is in the abnormal relationship, to the signal transmission paths, which serve as input paths to the comparison portions, if the inspection instruction signal is output from the signal output portion.

6. An onboard power supply device comprising:
the voltage conversion portion;
the control portion;
the abnormality detection portion; and
the failure detection device according to claim 1.

7. The failure detection device for the onboard power supply device according to claim 2,
wherein the voltage conversion portion includes a first element constituted by a switching element that is electrically connected to the first conductive path, a second element constituted by a switching element or a diode that is electrically connected between the first conductive path and a reference conductive path whose potential is kept at a predetermined reference potential that is lower than a potential in the first conductive path, and an inductor that is electrically connected between the first and second elements and the second conductive path,
the abnormality detection portion includes, as one of the abnormality detection circuits, an abnormality detection circuit on a reference conductive path side for detecting an abnormality in a current flowing between the second element and the reference conductive path, and
the signal distribution portion distributes the inspection instruction signal output from the signal output portion to the shared signal line at least to the abnormality detection circuit on the reference conductive path side.

8. The failure detection device for the onboard power supply device according to claim 2,
wherein the onboard power supply device is provided with a plurality of the voltage conversion portions,
the abnormality detection portion is provided with one or more abnormality detection circuits in association with the respective voltage conversion portions, and
the signal distribution portion distributes the inspection instruction signal output from the signal output portion to the shared signal line to the abnormality detection circuits associated with the respective voltage conversion portions.

9. The failure detection device for the onboard power supply device according to claim 3,
wherein the onboard power supply device is provided with a plurality of the voltage conversion portions,
the abnormality detection portion is provided with one or more abnormality detection circuits in association with the respective voltage conversion portions, and
the signal distribution portion distributes the inspection instruction signal output from the signal output portion to the shared signal line to the abnormality detection circuits associated with the respective voltage conversion portions.

10. The failure detection device for the onboard power supply device according to claim 2,
wherein the abnormality detection portion includes:
a plurality of signal transmission paths corresponding to the respective detection target positions;
a plurality of voltage signal input portions for applying voltage signals each corresponding to a voltage or a current at a corresponding one of the detection target positions to the respective signal transmission paths; and
a plurality of comparison portions corresponding to the respective voltage signal input portions,
each of the comparison portions compares, with a reference voltage, an input voltage applied to a corresponding one of the signal transmission paths by a corresponding one of the voltage signal input portions, outputs a normal signal if the input voltage and the reference voltage are in a predetermined normal relationship, and outputs an abnormal signal if the input voltage and the reference voltage are in an abnormal relationship that is not the normal relationship, and
the signal distribution portion applies a voltage with which the relationship between the input voltage and the reference voltage is in the abnormal relationship, to the signal transmission paths, which serve as input paths to the comparison portions, if the inspection instruction signal is output from the signal output portion.

11. The failure detection device for the onboard power supply device according to claim 3,
wherein the abnormality detection portion includes:
a plurality of signal transmission paths corresponding to the respective detection target positions;
a plurality of voltage signal input portions for applying voltage signals each corresponding to a voltage or a current at a corresponding one of the detection target positions to the respective signal transmission paths; and
a plurality of comparison portions corresponding to the respective voltage signal input portions,
each of the comparison portions compares, with a reference voltage, an input voltage applied to a corresponding one of the signal transmission paths by a corresponding one of the voltage signal input portions, outputs a normal signal if the input voltage and the reference voltage are in a predetermined normal relationship, and outputs an abnormal signal if the input voltage and the reference voltage are in an abnormal relationship that is not the normal relationship, and
the signal distribution portion applies a voltage with which the relationship between the input voltage and the reference voltage is in the abnormal relationship, to the signal transmission paths, which serve as input paths to the comparison portions, if the inspection instruction signal is output from the signal output portion.

12. The failure detection device for the onboard power supply device according to claim 4,
wherein the abnormality detection portion includes:
a plurality of signal transmission paths corresponding to the respective detection target positions;
a plurality of voltage signal input portions for applying voltage signals each corresponding to a voltage or a current at a corresponding one of the detection target positions to the respective signal transmission paths; and
a plurality of comparison portions corresponding to the respective voltage signal input portions,
each of the comparison portions compares, with a reference voltage, an input voltage applied to a corresponding one of the signal transmission paths by a corresponding one of the voltage signal input portions, outputs a normal signal if the input voltage and the reference voltage are in a predetermined normal relationship, and outputs an abnormal signal if the input voltage and the reference voltage are in an abnormal relationship that is not the normal relationship, and
the signal distribution portion applies a voltage with which the relationship between the input voltage and the reference voltage is in the abnormal relationship, to the signal transmission paths, which serve as input paths to the comparison portions, if the inspection instruction signal is output from the signal output portion.

13. The onboard power supply device set forth in claim 6, wherein the wherein the abnormality detection portion includes, as the plurality of abnormality detection circuits, an output current abnormality detection circuit for detecting an abnormality in a current in a conductive path on an output side of the voltage conversion portion, and an output voltage abnormality detection circuit for detecting an abnormality in a voltage in the conductive path on the output side, and
the signal distribution portion distributes the inspection instruction signal output from the signal output portion to the shared signal line at least to the output current abnormality detection circuit and the output voltage abnormality detection circuit.

14. The onboard power supply device set forth in claim 6, wherein the voltage conversion portion includes a first element constituted by a switching element that is electrically connected to the first conductive path, a second element constituted by a switching element or a diode that is electrically connected between the first conductive path and a reference conductive path whose potential is kept at a predetermined reference potential that is lower than a potential in the first conductive path, and an inductor that is electrically connected between the first and second elements and the second conductive path,
the abnormality detection portion includes, as one of the abnormality detection circuits, an abnormality detection circuit on a reference conductive path side for detecting an abnormality in a current flowing between the second element and the reference conductive path, and
the signal distribution portion distributes the inspection instruction signal output from the signal output portion to the shared signal line at least to the abnormality detection circuit on the reference conductive path side.

15. The onboard power supply device set forth in claim 6, wherein the onboard power supply device is provided with a plurality of the voltage conversion portions,
the abnormality detection portion is provided with one or more abnormality detection circuits in association with the respective voltage conversion portions, and
the signal distribution portion distributes the inspection instruction signal output from the signal output portion to the shared signal line to the abnormality detection circuits associated with the respective voltage conversion portions.

16. The onboard power supply device set forth in claim 6, wherein the abnormality detection portion includes:
a plurality of signal transmission paths corresponding to the respective detection target positions;
a plurality of voltage signal input portions for applying voltage signals each corresponding to a voltage or a current at a corresponding one of the detection target positions to the respective signal transmission paths; and
a plurality of comparison portions corresponding to the respective voltage signal input portions,
each of the comparison portions compares, with a reference voltage, an input voltage applied to a corresponding one of the signal transmission paths by a corresponding one of the voltage signal input portions, outputs a normal signal if the input voltage and the reference voltage are in a predetermined normal relationship, and outputs an abnormal signal if the input voltage and the reference voltage are in an abnormal relationship that is not the normal relationship, and
the signal distribution portion applies a voltage with which the relationship between the input voltage and the reference voltage is in the abnormal relationship, to the signal transmission paths, which serve as input paths to the comparison portions, if the inspection instruction signal is output from the signal output portion.
